(19) United States
(12) Patent Application Publication
(10) Pub. No.: US 2007/0164794 A1
(43) Pub. Date: Jul. 19, 2007

(54) DIFFERENTIAL PAIR SIGNAL LINES MATCHING CIRCUIT

(75) Inventor: Jin-Bo Qiu, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,713

(22) Filed: Sep. 15, 2006

(30) Foreign Application Priority Data
Jan. 13, 2006 (CN) 200610032958.4

(51) Int. Cl. H03B 1/00

(52) U.S. Cl. 327/108

(57) ABSTRACT

A differential pair signal lines matching circuit includes a pair of differential pair signal lines coupled to a receiver, a first terminal resistor, a second terminal resistor, and a capacitor. The first terminal resistor is coupled at one end to one of the differential pair signal lines near the receiver. The second terminal resistor is coupled at one end to another one of the differential pair signal lines near the receiver. The capacitor is coupled between the other ends of the first terminal resistor and the second terminal resistor. The differential pair matching circuit eliminates noise and non-monotonic glitches of a signal transmitted on differential pair signal lines without influencing a signal voltage thereof.

### FIELD OF THE INVENTION

The present invention relates to differential pair signal lines matching circuits, and particularly to a differential pair signal lines matching circuit with terminal resistor and capacitor.

### DESCRIPTION OF RELATED ART

In digital circuits, it is common to represent a binary “zero” with one voltage level and a binary “one” with another voltage level. By way of example, a logical “one” might be represented by a +5 volt signal and a logical “zero” by a 0 volt signal on a given signal line. Inasmuch as voltages are relative, it is common to reference the signal level to ground. Signals formed in this way are referred to as single-ended signals.

One disadvantage of this scheme is that the noise margin, or level between the guaranteed zero and one levels, is relatively small. It is preferable, i.e., more definite, to have a large noise margin. This is especially true at high frequencies where settling times can be relatively long due to ringing and other high frequency components of fast-rise signals.

The above-described disadvantages can be avoided by the use of differential pair signal transmission means. In this way, the signal state is not referenced from either ground or a high level but is based on the voltage difference between the two signals being above a given level. This scheme approximately doubles the noise margin as compared to single-ended cases.

FIG. 2 shows a conventional differential pair signal lines matching circuit for eliminating noise and non-monotonic glitches of differential pair signal lines. The differential pair matching circuit includes a pair of differential pair signal lines 12a and 12b coupled to a receiver 14, and a terminal resistor R0.

The terminal resistor R0 is coupled between the differential pair signal lines 12a and 12b near the receiver 14. The resistance of the terminal resistor R0 matches the sum of resistances of the differential pair signal lines 12a and 12b. For example, the resistance of each of the signal lines 12a and 12b is 50Ω, therefore the resistance of the terminal resistor R0 is about 100Ω.

FIG. 3 shows another conventional differential pair signal lines matching circuit that includes a pair of differential pair signal lines 22a and 22b coupled to a receiver 24, two terminal resistors R1 and R2, and a capacitor C0. The terminal resistors R1 and R2 are coupled between the differential pair signal lines 22a and 22b in series. A terminal of the capacitor C0 is coupled to a node between the terminal resistors R1 and R2, and another terminal of the capacitor C0 is coupled to ground.

The differential pair signal lines matching circuits as shown in FIG. 2 and FIG. 3 may eliminate noise and non-monotonic glitches of differential pair signal lines. However, a signal voltage transmitted over the differential pair signal lines will be divided because of the terminal resistors.

What is needed, therefore, is a differential pair matching circuit for eliminating noise and non-monotonic glitches of a signal transmitted on differential pair signal lines without influencing a signal voltage thereof.

### SUMMARY OF THE INVENTION

An exemplary differential pair signal lines matching circuit includes a pair of differential pair signal lines coupled to a receiver, a first terminal resistor, a second terminal resistor, and a capacitor. The first terminal resistor is coupled at one end to one of the differential pair signal lines near the receiver. The second terminal resistor is coupled at one end to another one of the differential pair signal lines near the receiver. The capacitor is coupled between the other ends of the first terminal resistor and the second terminal resistor.

Other advantages and novel features will become more apparent from the following detailed description when taken in conjunction with the accompanying drawings, in which:

### BRIEF DESCRIPTION OF THE DRAWINGS

FIG. 1 is a circuit diagram of one embodiment of a differential pair signal lines matching circuit in accordance with the present invention;

FIG. 2 is a circuit diagram of a conventional differential pair signal lines matching circuit; and

FIG. 3 is a circuit diagram of another conventional differential pair signal lines matching circuit.

### DETAILED DESCRIPTION OF THE INVENTION

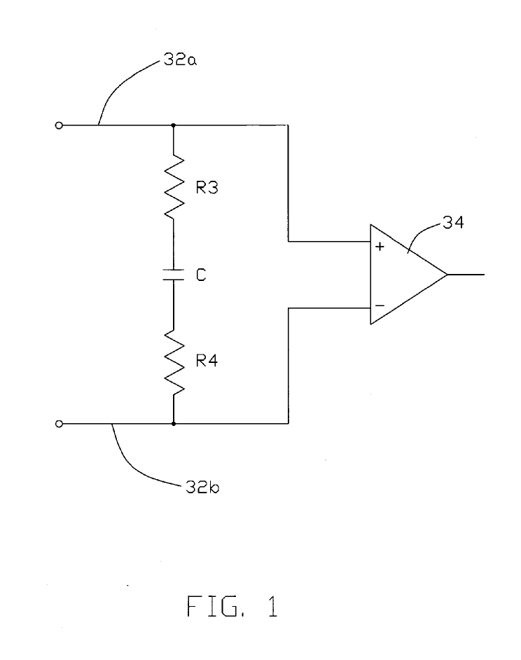

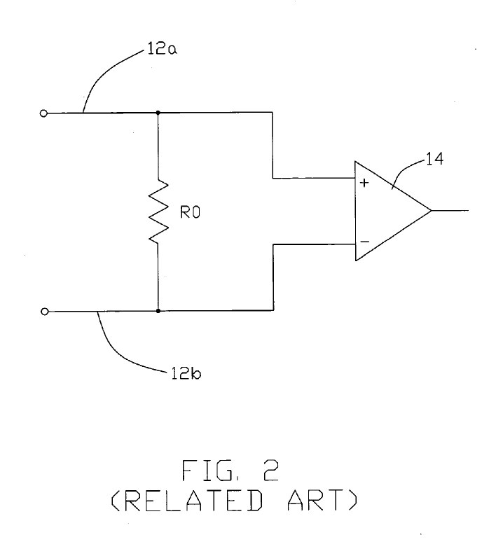

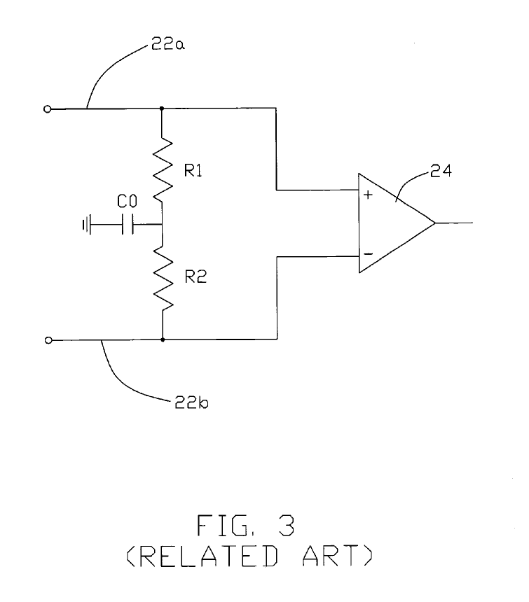

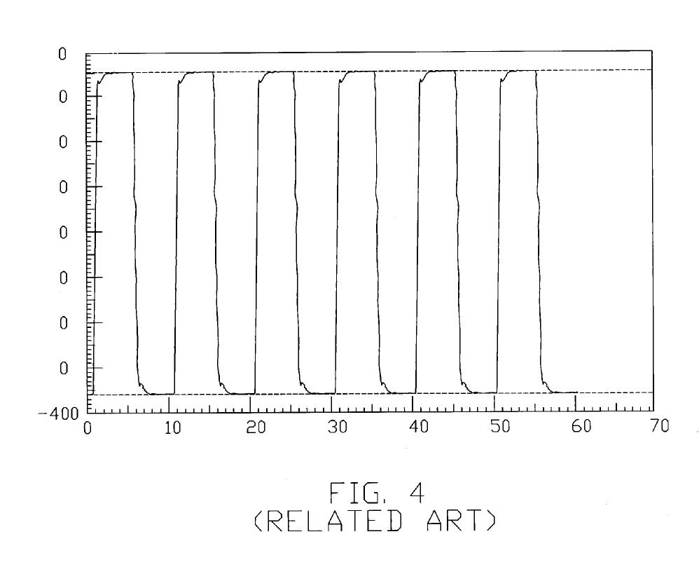

Referring to FIG. 1, a differential pair signal lines matching circuit in accordance with a preferred embodiment of the present invention includes a pair of differential pair signal lines 32a and 32b coupled to a receiver 34, a first terminal resistor R3, a second terminal resistor R4, and a capacitor C.

The first terminal resistor R3 is coupled between the differential pair signal line 32a near the receiver 34 and an end of the capacitor C. The second terminal resistor R4 is coupled between the differential pair signal line 32b near the receiver 34 and the other end of the capacitor C.

The first terminal resistor R3 and the second terminal resistor R4 have a same distance to the receiver 34. The first terminal resistor R3 and the second terminal resistor R4 have a same resistance, and the sum of the resistances match a sum of resistances of the differential pair signal lines 32a and 32b.

At a rising edge or a falling edge of a signal voltage transmitted on the differential pair signal lines 32a and 32b, the capacitor C will be charged up and make the first terminal resistor R3 and the second terminal resistor R4 connected in series. Then, the first terminal resistor R3 and the second terminal resistor R4 will essentially eliminate noise and non-monotonic glitches of the signal transmitted on the differential pair signal lines 32a and 32b.

Subsequently, the capacitor C finishes charging, and acts as an open between the first terminal resistor R3 and the second terminal resistor R4. Thus, the first terminal resistor R3 and the second terminal resistor R4 will not act as a voltage divider on the differential pair signal lines 32a and 32b once the signal voltage is going steady. Therefore, the differential pair signal lines matching circuit as shown in FIG. 1 may eliminate noise and non-monotonic glitches of the signal transmitted on the differential pair signal lines 32a and 32b, and reduce the influence on the signal voltage.

It is believed that the present invention and its advantages will be understood from the foregoing description, and it will be apparent that various changes may be made thereto without departing from the spirit and scope of the invention or sacrificing all of its material advantages, the example hereinbefore described merely being a preferred or exemplary embodiment of the invention.

What is claimed is:

1. A differential pair signal lines matching circuit comprising:
a pair of differential pair signal lines coupled to a receiver;
a first terminal resistor having an end connected to one of the differential pair signal lines near the receiver;
a second terminal resistor having an end connected to another one of the differential pair signal lines near the receiver; and
a capacitor coupled between other ends of the first terminal resistor and the second terminal resistor.

2. The differential pair signal lines matching circuit as claimed in claim 1, wherein the first terminal resistor and the second terminal resistor have a same distance to the receiver.

3. The differential pair signal lines matching circuit as claimed in claim 1, wherein the first terminal resistor and the second terminal resistor have a same resistance, and a sum of the resistances of the first terminal resistor and the second terminal resistor matches a sum of resistances of the differential pair signal lines.
